(19) United States
(12) Patent Application Publication
(10) Pub. No.: US 2011/0095417 A1
(43) Pub. Date: Apr. 28, 2011

(54) LEADLESS SEMICONDUCTOR DEVICE TERMINAL

(75) Inventors: Jocel P. Gomez, Lapu-Lapu City (PH); Consuelo N. Tangpuz, Lapu-Lapu City (PH)

(73) Assignee: Fairchild Semiconductor Corporation, South Portland, ME (US)

(21) Appl. No.: 12/607,294

(22) Filed: Oct. 28, 2009

(51) Int. Cl. H01L 23/498

(52) U.S. Cl. 257/737; 257/E23.068

(57) ABSTRACT

This document discusses, among other things, a semiconductor die having a first conductive bump coupled to a first electrical terminal at a first die surface of a semiconductor die and a dielectric substantially covering the first die surface and substantially surrounding the first conductive bump. A surface of the dielectric can include a recessed terminal area, and a second electrical terminal can be coupled to the first conductive bump in the recessed terminal area.

### BACKGROUND

In semiconductor manufacturing, an integrated circuit die can be coupled to a printed circuit board or an integrated circuit package using one or more conductive bumps.

### OVERVIEW

This document discusses, among other things, a semiconductor die having a first conductive bump coupled to a first electrical terminal at a first die surface of a semiconductor die and a dielectric substantially covering the first die surface and substantially surrounding the first conductive bump. In an example, the dielectric can be configured to support the first conductive bump or the semiconductor die, or to secure the first conductive bump to the first die surface. In certain examples, the dielectric can include a polymer configured to be activated to conductive plating deposition using laser ablation, and a second terminal can be formed on the dielectric, coupled to the first conductive bump, using laser ablation and conductive plating deposition.

In Example 1, a semiconductor device includes a semiconductor die having a first die surface and a first electrical terminal at the first die surface, a first copper (Cu) bump having a first bump surface coupled to the first electrical terminal and a second opposite bump surface, a dielectric configured to be activated to Cu plating deposition using laser ablation, the dielectric substantially covering the first die surface and substantially surrounding the first Cu bump between the first and second bump surfaces, the dielectric having a first dielectric surface proximate the first die surface and a second dielectric surface opposite the first dielectric surface, the second dielectric surface including a recessed terminal area, a second electrical terminal coupled to the second bump surface in the recessed terminal area, the second electrical terminal configured to provide an electrical connection to the first electrical terminal at the first die surface, wherein the recessed terminal area includes a recess created using laser ablation of the second dielectric surface, and wherein the recessed terminal area includes the second bump surface, and wherein the second electrical terminal includes a laser activated Cu plating deposition in the recessed terminal area.

In Example 2, a semiconductor device includes a semiconductor die having a first die surface and a first electrical terminal at the first die surface, a first conductive bump having a first bump surface coupled to the first electrical terminal and a second opposite bump surface, a dielectric substantially covering the first die surface and substantially surrounding the first conductive bump between the first and second bump surfaces, the dielectric having a first dielectric surface proximate the first die surface and a second dielectric surface opposite the first dielectric surface, the second dielectric surface including a recessed terminal area, and a second electrical terminal coupled to the second bump surface in the recessed terminal area, the second electrical terminal configured to provide an electrical connection to the first electrical terminal at the first die surface.

In Example 3, the dielectric of any one or more of Examples 1-2 optionally includes a polymer configured to be activated to conductive plating deposition using laser ablation, and wherein the recessed terminal area includes a recess created using laser ablation of the second dielectric surface, and the second electrical terminal of any one or more of Examples 1-2 optionally includes a laser activated conductive plating deposition in the recessed terminal area.

In Example 4, the recessed terminal area of any one or more of Examples 1-3 optionally includes the second bump surface.

In Example 5, the second bump surface of any one or more of Examples 1-4 is optionally exposed in the recessed terminal area using laser ablation of the second dielectric surface.

In Example 6, the first conductive bump of any one or more of Examples 1-5 optionally includes a first copper (Cu) bump, wherein the polymer includes a polymer configured to be activated to Cu plating deposition using laser ablation, and wherein the second electrical terminal includes a laser activated Cu plating deposition.

In Example 7, the polymer of any one or more of Examples 1-6 optionally includes at least one of thermoplastic, crosslink, an epoxy mold compound (EMC), or a Polybutylene Terephthalate (PBT).

In Example 8, any one or more of Examples 1-7 optionally includes a second conductive bump coupled to the second electrical terminal, wherein the second conductive bump includes a solder bump configured to provide a contact for external board mounting soldering.

In Example 9, the second electrical terminal of any one or more of Examples 1-8 optionally includes the second conductive bump.

In Example 10, the first conductive bump of any one or more of Examples 1-9 optionally includes a first Cu bump having a first distance between the first and second bump surfaces, and wherein the dielectric includes a thickness corresponding to the first distance of the first conductive bump.

In Example 11, the first conductive bump of any one or more of Examples 1-10 optionally includes a substantially round portion having the first bump surface opposite the second bump surface.

In Example 12, the recessed terminal area of any one or more of Examples 1-11 optionally includes a shape formed at the second dielectric surface using laser ablation, and wherein the second electrical terminal is configured to be deposited in the recessed terminal area, taking the shape of the recessed terminal area.

In Example 13, the shape of the second electrical terminal of any one or more of Examples 1-12 optionally includes at least one of a circular shape, a square shape, or a rectangular shape.

In Example 14, the dielectric of any one or more of Examples 1-13 optionally includes a polymer configured to provide rigid support between the first conductive bump and the first electrical terminal at the first die surface.

In Example 15, the semiconductor die of any one or more of Examples 1-14 optionally includes a stacked die.

In Example 16, the semiconductor die of any one or more of Examples 1-15 optionally includes a plurality of first electrical terminals at the first die surface and a plurality of corresponding first conductive bumps coupled to each of the plurality of electrical terminals, and the recessed terminal area of any one or more of Examples 1-15 optionally covers at least two of the plurality of first conductive bumps, wherein the second electrical terminal is coupled to the at least two of the plurality of first conductive bumps in the recessed terminal area.

In Example 17, the dielectric of any one or more of Examples 1-16 optionally includes a polymer configured to be activated to conductive plating deposition using laser ablation, and wherein the recessed terminal area includes a recess created using laser ablation of the second dielectric surface, and the second electrical terminal of any one or more of Examples 1-16 optionally includes a laser activated conductive plating deposition in the recessed terminal area.

In Example 18, a semiconductor device includes a semiconductor die having a first die surface and a plurality of first electrical terminals at the first die surface, a plurality of first conductive bumps corresponding to each of the plurality of electrical terminals at the first die surface, each of the first conductive bumps having a first bump surface coupled to one of the plurality of electrical terminals and having a second opposite bump surface, a dielectric substantially covering the first die surface and substantially surrounding the plurality of first conductive bumps between the first and second bump surfaces of each first conductive bump, the dielectric having a first dielectric surface proximate the first die surface and a second dielectric surface opposite the first dielectric surface, the second dielectric surface including a recessed terminal area, a second electrical terminal coupled to at least one of the second bump surfaces in one of the recessed terminal configured to provide an electrical connection to at least one of the plurality of first electrical terminals at the first die surface, wherein the dielectric includes a polymer configured to be activated to plating deposition using laser ablation, and wherein the recessed terminal area includes a recess created using laser ablation of the second surface, and wherein the second electrical terminal includes a laser activated conductive plating deposition in the recessed terminal area.

In Example 19, the plurality of first conductive bumps of any one or more of Examples 1-18 optionally includes a plurality of first Cu bumps, wherein the polymer includes a polymer configured to be activated to copper plating deposition using laser ablation, and wherein the second electrical terminal includes a laser activated copper plating deposition.

In Example 20, the recessed terminal area of any one or more of Examples 1-19 optionally includes at least one second bump surface of one or more of the plurality of first conductive bumps.

In Example 21, a method can include forming a first conductive bump on a first electrical terminal on a die surface of a semiconductor die, substantially covering the first die surface and substantially surrounding the first conductive bump using a dielectric, providing a recessed terminal area in the dielectric, and forming a second electrical terminal coupled to the first conductive bump in the recessed terminal area, the electrical terminal configured to provide an electrical connection to the first electrical terminal at the first die surface.

In Example 22, the substantially covering the first die surface and substantially surrounding the first conductive bump of any one or more of Examples 1-21 optionally includes using a polymer configured to be activated to conductive plating deposition using laser ablation, and the providing the recessed terminal area and the forming the electrical terminal of any one or more of Examples 1-21 optionally includes using laser ablation of the polymer.

In Example 23, the providing the recessed terminal area of any one or more of Examples 1-22 optionally includes exposing at least a portion of the first conductive bump.

In Example 24, the forming the first conductive bump of any one or more of Examples 1-23 optionally includes forming a first copper (Cu) bump, the substantially covering the first die surface and substantially surrounding the first conductive bump of any one or more of Examples 1-23 optionally includes using a polymer configured to be activated to Cu plating deposition using laser ablation, and the forming the electrical terminal of any one or more of Examples 1-23 optionally includes using a laser activated Cu plating deposition.

In Example 25, the substantially covering the first die surface and substantially surrounding the first conductive bump of any one or more of Examples 1-24 optionally includes using at least one of thermoplastic, crosslink, an epoxy mold (EMC) compound, or a Polybutylene Terephthalate (PBT).

In Example 26, any one or more of Examples 1-25 optionally includes forming a second conductive bump on the second electrical terminal.

In Example 27, the substantially covering the first die surface and substantially surrounding the first conductive bump using the dielectric of any one or more of Examples 1-26 optionally includes providing rigid support between the first conductive bump and the first electrical terminal.

In Example 28, the forming the first conductive bump of any one or more of Examples 1-27 optionally includes forming a plurality of first conductive bumps on a plurality of first electrical terminals on the first die surface, the providing the recessed terminal area of any one or more of Examples 1-27 optionally includes providing a recessed terminal area over at least two of the plurality of first conductive bumps, and the forming the second electrical terminal of any one or more of Examples 1-27 optionally includes forming a second electrical terminal coupled to the at least two of the plurality of first conductive bumps, providing an electrical connection to at least two of the plurality of first electrical terminals on the first die surface.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example of an isometric view of a system, partially removed.

FIG. 2 illustrates generally an example of terminal pad formation through laser ablation.

FIG. 3 illustrates generally an example of a section view of a system.

FIG. 4 illustrates generally an example of a section view of a system including solder bumps.

FIGS. 5-12 illustrate generally an example of an assembly process flow including laser ablation surface activation of a polymer surface.

FIGS. 13-15 illustrate generally example terminal formation options.

### DETAILED DESCRIPTION

In certain examples, solder bumps can be attached to a semiconductor die prior to coupling the semiconductor die to a printed circuit board or an integrated circuit package. In various examples, solder bumps can crack, can become detached, or can be otherwise compromised, for example, due to thermal changes or mechanical stresses of or on the solder bumps. Further, in semiconductor manufacturing, changing the size, shape, or configuration of an integrated circuit terminal can require one or more different masks.

The present inventors have recognized, among other things, that a dielectric can be configured to support a first conductive bump coupled to a first terminal on a semiconductor die. Further, the present inventors have recognized that the dielectric can include a polymer configured to be activated to conductive plating deposition using laser ablation, and that a second terminal can be formed on the dielectric, coupled to the first conductive bump, using laser ablation and conductive plating deposition (e.g., copper (Cu) plating deposition).

In an example, a molded chip scale semiconductor device can include one or more terminals coupled to one or more conductive bumps or conductive bumped structures (e.g., Cu bump, etc.). In an example, a conductive bump can be directly bonded on a device terminal or a device die bonding pad.

In certain examples, one or more semiconductor device terminals (e.g., one or more wafer level semiconductor device terminals) can be formed using a molded surface. In an example, the molded surface can include a polymer material (e.g., thermoplastic, crosslink, or one or more other polymer materials) activated to conductive plating deposition (e.g., Cu plating deposition) when the surface of the polymer material is ablated using a laser. In certain examples, the polymer material can replace the conventional printed circuit board (PCB) and can be used to form a semiconductor device terminal. Further, the polymer material can be applied on leadless or bump molded chip scale packages.

In an example, the semiconductor device disclosed herein can include a chip scale package having a smaller footprint or a thinner or lighter weight package than a conventional leadframe based molded device and can be applied to portable (e.g., ultraportable) products requiring condensed circuitry or small size. In certain examples, the semiconductor device terminal disclosed herein can be applied to a leadless or a bump molded chip scale package, stacked dies, or a die coupled to a metal structure (e.g., a frame, a heat sink, etc.).

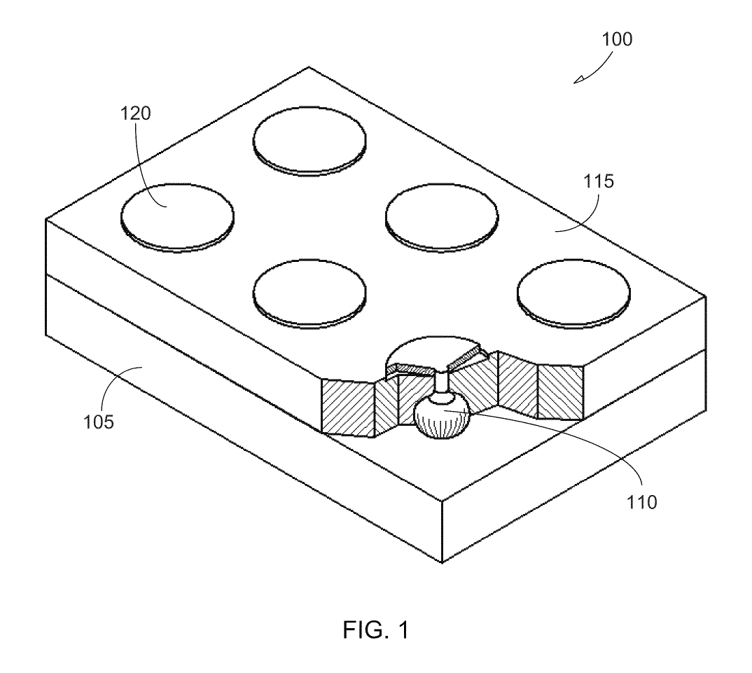

FIG. 1 illustrates generally an example of a partially removed isometric view of a system 100, including a semiconductor die 105, a first conductive bump 110 coupled to the semiconductor die 105, a dielectric 115 substantially surrounding the first conductive bump 110 and covering the semiconductor die 105, and a terminal 120 formed on the polymer 115 and coupled to the first conductive bump 110.

In an example, the semiconductor die 105 can include a wafer-level chip scale semiconductor device having a first terminal (e.g., a device die bonding pad) on a first die surface. In an example, the first conductive bump 110 can include a first bump surface directly bonded to or otherwise in contact with the first terminal. In an example, the first conductive bump 110 can include a Cu bump or one or more other conductive bumps coupled to the semiconductor die 105, and the dielectric 115 can be configured to support the first conductive bump 110, or one or more other conductive bumps, between the first bump surface and a second bump surface on the semiconductor die 105. In an example, the second bump surface can include a top of the first conductive bump 110. In other examples, the second bump surface can include at least a portion of the surface of the first conductive bump 110 not in contact with the semiconductor die 105.

In an example, the dielectric 115 can include a polymer or other dielectric material configured to be activated to conductive plating deposition using laser ablation. In an example, the dielectric 115 can include thermoplastic, crosslink, an epoxy mold compound (EMC), polybutylene terephthalate (PBT), or one or more other dielectrics. In an example, the dielectric 115 can at least partially include a conductive component, such as one or more metallic compounds mixed into the dielectric material (e.g., an organometallic complex, etc.). In certain examples, the dielectric 115 can be substantially reduced to the metallic compound, or otherwise activated to conductive plating deposition, by irradiation with a laser (e.g., a CO₂ laser).

In other examples, the dielectric 115 can include one or more other materials (e.g., a polymer matrix material including non-conductive polyacrylonitrile fibers) that, when subjected to laser irradiation, can carbonize, pyrolize, or otherwise decompose to form a conductive network that can be converted to a desired metallization thickness by chemical or electroplating reinforcement.

In certain examples, the dielectric 115 can be modified using a laser without a conductive phase forming locally, such as by creating catalytic centres on a dielectric material, or by using fine ceramic particles or catalytic micro-capsule or other fillers that can serve as sees for a following metallization process. Further, in various examples, the dielectric 115 can include an at least partially translucent mold compound, allowing visibility of the semiconductor die 105, the first conductive bump 110, or one or more other features of the device, reducing the need for added fiducial markers for laser ablation reference.

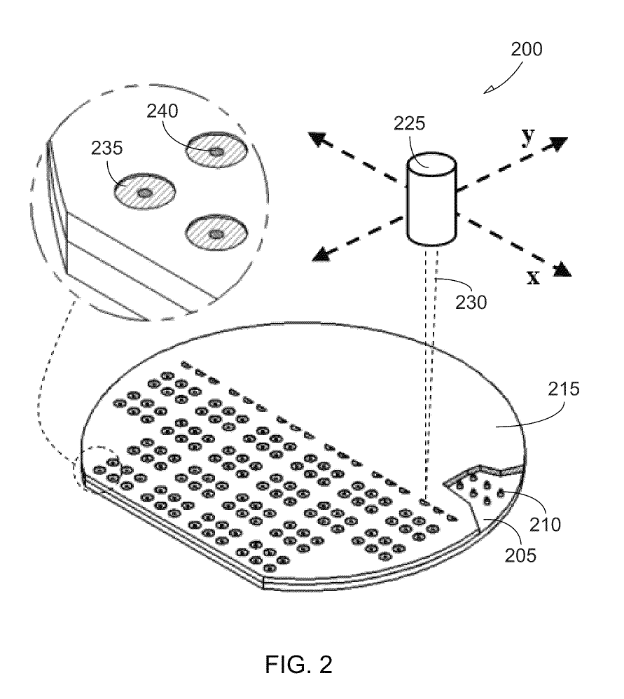

FIG. 2 illustrates generally an example of terminal pad formation 200 through laser ablation. In an example, a conductive bump 210 can be coupled to a semiconductor die 205 (or a semiconductor wafer), and a dielectric 215 (e.g., a molded polymer) can substantially cover a first die surface of the semiconductor die 205 and substantially surround the first conductive bump 210. In an example, a laser head 225 can be positioned over the dielectric 215, and energy (e.g., laser 230) can be applied to the dielectric 215, forming a recessed terminal area 235 in the dielectric 215 (e.g., in a top surface of the dielectric 215), and, in certain examples, exposing a second bump surface 240 of the first conductive bump 210.

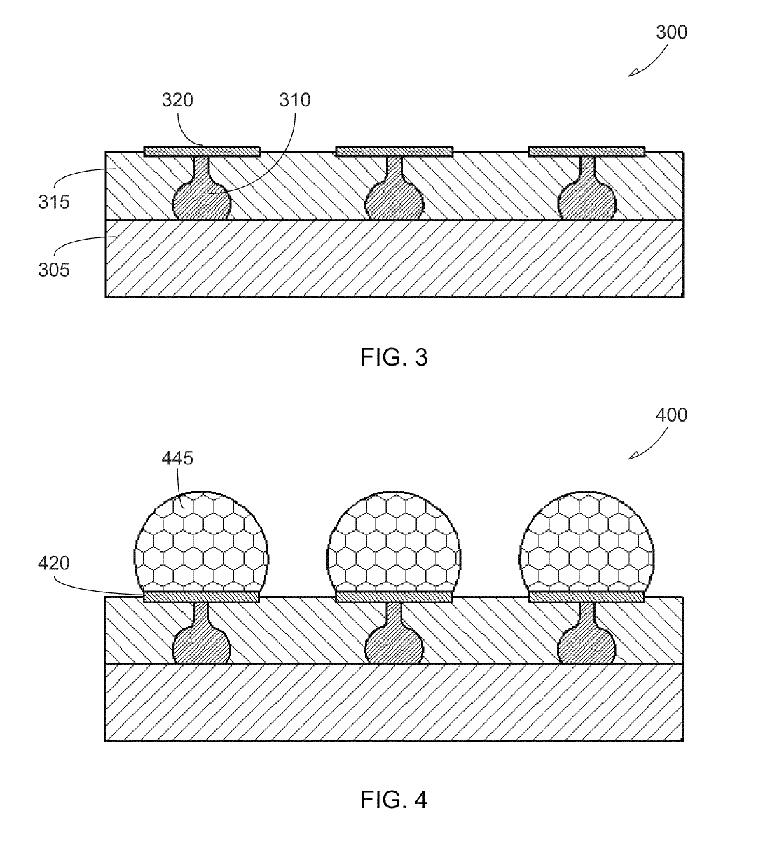

FIG. 3 illustrates generally an example of a section view of a system 300 including a first conductive bump 310 having a first bump surface coupled to a first die surface of a semiconductor die 305 (e.g., to a first electric terminal at a first die surface of the semiconductor die). In an example, a dielectric 315 can be configured to substantially cover at least a portion of the first die surface and to substantially surround the first conductive bump 310 between the first bump surface and a second bump surface (e.g., between the bottom and top of the first conductive bump 310).

In various examples, the dielectric 315 can be configured to support the semiconductor die 305 or the first conductive bump 310, or to secure the first conductive bump 310 to the semiconductor die 305, in certain examples, providing a rigid device, less susceptible to mechanical or thermal stresses.

In an example, a recessed terminal area can be formed at a surface of the dielectric 315 (e.g., using laser ablation). In certain examples, the recessed terminal area can expose at least a portion of the first conductive bump 310, and a second electrical terminal 320 can be formed in the recessed terminal area coupled to a first conductive bump 310.

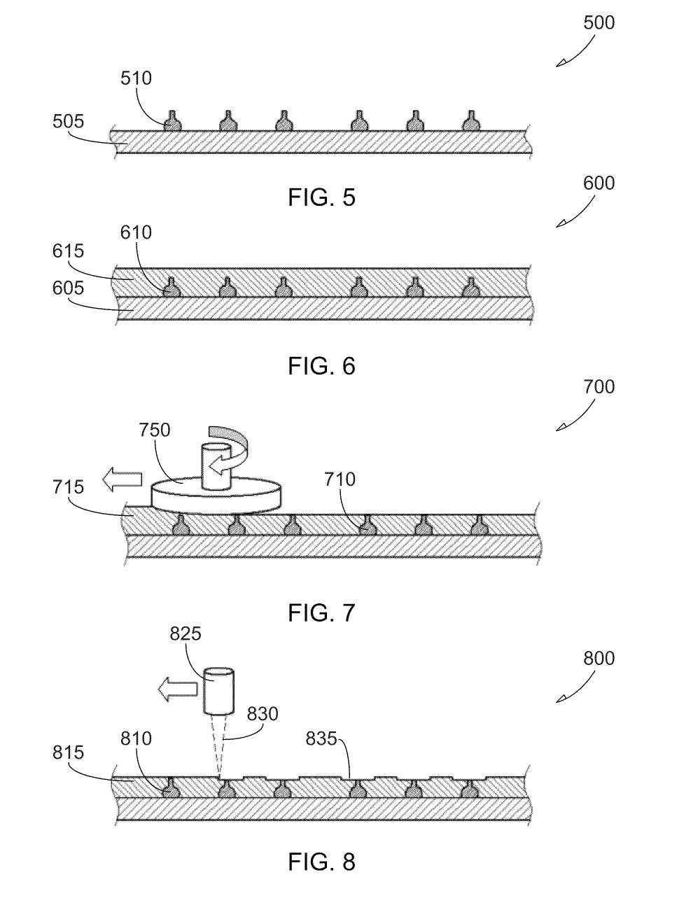

FIG. 4 illustrates generally an example of a section view of a system 400 including a second conductive bump 445 coupled to a second electrical terminal 420. In an example, the second conductive bump 445 can include a Cu bump, a solder bump, or one or more other conductive bumps.

### Process Examples

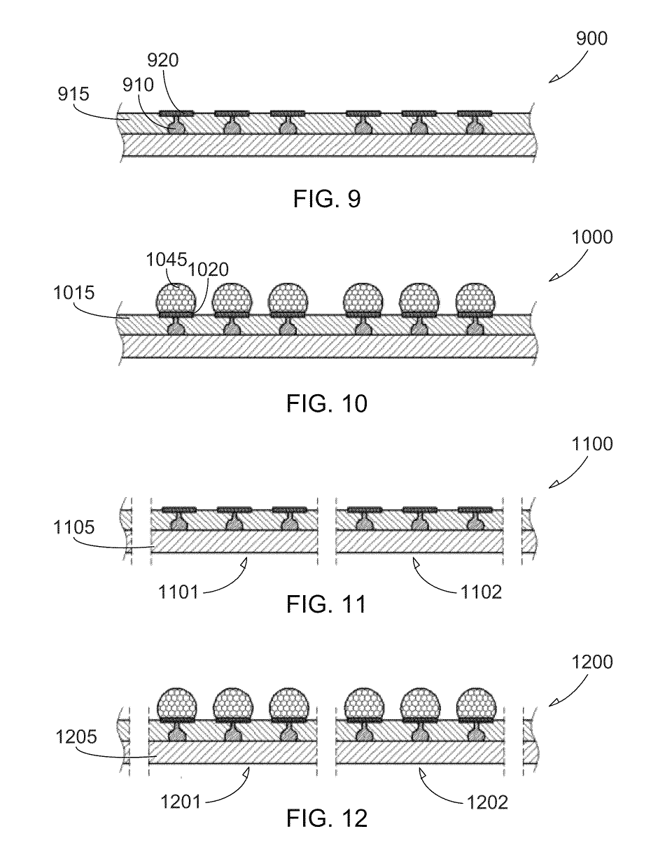

FIGS. 5-12 illustrate generally an example of an assembly process flow including laser ablation surface activation of a polymer surface.

FIG. 5 illustrates generally an example of a process step 500 including forming a first conductive bump 510 at a first surface of a semiconductor die 505. In an example, the first conductive bump 510 can include a Cu bump, a solder bump, or one or more other conductive bumps. The first conductive bump 510 can be formed on a first electrical terminal (e.g., a device die bonding pad) at the first surface of the semiconductor die 505.

FIG. 6 illustrates generally an example of a process step 600 including forming (e.g., molding) a dielectric 615 on at least a portion of a first surface of a semiconductor die 605, substantially surrounding a first conductive bump 610 formed on the semiconductor die 605.

In certain examples, the dielectric 615 can partially surround the first conductive bump 610, or the dielectric 615 can completely surround the first conductive bump 610.

FIG. 7 illustrates generally an example of a process step 700 including removing at least a portion of a dielectric 715 covering a first conductive bump 710. In an example, the top surface of the dielectric 715 can be grinded or otherwise removed (e.g., using a grinder 750) to expose at least a portion of a first conductive bump 710 coupled to a semiconductor die 705 or to reduce the thickness of the dielectric 715 over the first conductive bump 710.

FIG. 8 illustrates generally an example of a process step 800 including applying laser 830 to a surface of a dielectric 815 to provide a recessed terminal area 835 in the dielectric 815 using a laser head 825. In an example, at least a portion of a first conductive bump 810 can be exposed in the recessed terminal area 835 using the laser 830.

In certain examples, the dielectric 815 can include a fully dielectric material, or a dielectric material having a metallic or other component. In an example, the dielectric 815 can be activated to conductive plating deposition using laser ablation.

FIG. 9 illustrates generally an example of a process step 900 including forming a second electrical terminal 920 in a recessed terminal area in a dielectric 915 using laser activated conductive plating. In an example, the second electrical terminal 920 can be coupled to a first conductive bump 910. In an example, the conductive plating can include Cu plating, finish plating, or one or more other conductive plating (e.g., using one or more other electroless or electroplating processes).

In an example, laser ablation of the dielectric 915 can free seeds on the surface of the material, enabling selective wet-chemical reduction metal precipitation. In other examples, one or more other methods utilizing laser ablation can be used to form the second electrical terminal 920.

FIG. 10 illustrates generally an example of a process step 1000 including forming a second conductive bump 1045 on a second electrical terminal 1020 at a surface of a dielectric 1015. In an example, the second conductive bump 1045 can include a Cu bump, a solder bump, or one or more other conductive bumps.

FIGS. 11-12 illustrate generally examples of process steps 1100, 1200 including sawing or otherwise separating a semiconductor die 1105, 1205 into more than one separate device, including a first device 1101, 1201 and a second device 1102, 1202. In certain examples, following separation from the semiconductor die 1105, 1205, the separate devices can be tested, marked, or packaged (e.g., tape and reel).

In certain examples, one or more of process steps 500-1200 can be excluded, or one or more other process steps or variations can be introduced to those described above.

### Example Terminal Formations

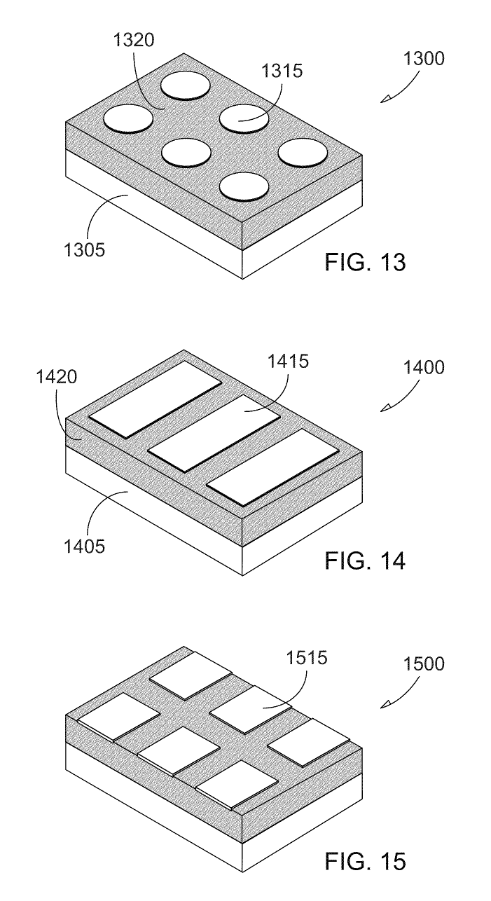

FIGS. 13-15 illustrate generally example terminal formation options using laser ablation of the dielectric.

FIG. 13 illustrates generally an example of a system 1300 including a semiconductor die 1305, a dielectric 1320 substantially covering a surface of the semiconductor die 1305, and a second electrical terminal 1315 (e.g., an exposed terminal), coupled to the semiconductor die, formed at a surface of the dielectric 1320 using laser ablation. In an example, the second electrical terminal 1315 can include a laser-activated conductive plating deposition in a recessed terminal area formed at the surface of the dielectric 1320 using laser ablation. In the example of FIG. 13, the exposed terminal includes a circular shape.

FIG. 14 illustrates generally an example of a system 1400 including a second electrical terminal 1415 formed in an extended rectangular shape. In certain examples, the second electrical terminal 1415 can be coupled to one or more conductive bumps bonded or otherwise coupled to one or more terminals or bonding pads of a semiconductor die 1405.

FIG. 15 illustrates generally an example of a system 1500 including a second electrical terminal 1515 formed in a square or rectangular shape. In an example, the shape of the second electrical terminal can be user-configurable (e.g., depending on specific design constraints). In an example, the shape or pattern is limited only by the constraints of the laser, eliminating the need for different mask sets for various patterns of plated surfaces.

### Additional Notes

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. In other examples, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. A semiconductor device comprising:
a semiconductor die having a first die surface and a first electrical terminal at the first die surface;
a first copper (Cu) bump having a first bump surface coupled to the first electrical terminal and a second opposite bump surface;
a dielectric configured to be activated to Cu plating deposition using laser ablation, the dielectric substantially covering the first die surface and substantially surrounding the first Cu bump between the first and second bump surfaces, the dielectric having a first dielectric surface proximate the first die surface and a second dielectric surface opposite the first dielectric surface, the second dielectric surface including a recessed terminal area;
a second electrical terminal coupled to the second bump surface in the recessed terminal area, the second electrical terminal configured to provide an electrical connection to the first electrical terminal at the first die surface;
wherein the recessed terminal area includes a recess created using laser ablation of the second dielectric surface, and wherein the recessed terminal area includes the second bump surface; and
wherein the second electrical terminal includes a laser activated Cu plating deposition in the recessed terminal area.

2. A semiconductor device comprising:
a semiconductor die having a first die surface and a first electrical terminal at the first die surface;
a first conductive bump having a first bump surface coupled to the first electrical terminal and a second opposite bump surface;
a dielectric substantially covering the first die surface and substantially surrounding the first conductive bump between the first and second bump surfaces, the dielectric having a first dielectric surface proximate the first die surface and a second dielectric surface opposite the first dielectric surface, the second dielectric surface including a recessed terminal area; and
a second electrical terminal coupled to the second bump surface in the recessed terminal area, the second electrical terminal configured to provide an electrical connection to the first electrical terminal at the first die surface.

3. The semiconductor device of claim 2, wherein the dielectric includes a polymer configured to be activated to conductive plating deposition using laser ablation, and wherein the recessed terminal area includes a recess created using laser ablation of the second dielectric surface; and
wherein the second electrical terminal includes a laser activated conductive plating deposition in the recessed terminal area.

4. The semiconductor device of claim 3, wherein the recessed terminal area includes the second bump surface.

5. The semiconductor device of claim 4, wherein the second bump surface is exposed in the recessed terminal area using laser ablation of the second dielectric surface.

6. The semiconductor device of claim 3, wherein the first conductive bump includes a first copper (Cu) bump, wherein the polymer includes a polymer configured to be activated to Cu plating deposition using laser ablation, and wherein the second electrical terminal includes a laser activated Cu plating deposition.

7. The semiconductor device of claim 3, wherein the polymer includes at least one of thermoplastic, crosslink, an epoxy mold compound (EMC), or a Polybutylene Terephthalate (PBT).

8. The semiconductor device of claim 3, including a second conductive bump coupled to the second electrical terminal, wherein the second conductive bump includes a solder bump configured to provide a contact for external board mounting soldering.

9. The semiconductor device of claim 8, wherein the second electrical terminal includes the second conductive bump.

10. The semiconductor device of claim 2, wherein the first conductive bump includes a first Cu bump having a first distance between the first and second bump surfaces, and wherein the dielectric includes a thickness corresponding to the first distance of the first conductive bump.

11. The semiconductor device of claim 2, wherein the first conductive bump includes a substantially round portion having the first bump surface opposite the second bump surface.

12. The semiconductor device of claim 2, wherein the recessed terminal area includes a shape formed at the second dielectric surface using laser ablation, and wherein the second electrical terminal is configured to be deposited in the recessed terminal area, taking the shape of the recessed terminal area.

13. The semiconductor device of claim 12, wherein the shape of the second electrical terminal includes at least one of a circular shape, a square shape, or a rectangular shape.

14. The semiconductor device of claim 2, wherein the dielectric includes a polymer, and wherein the polymer is configured to provide rigid support between the first conductive bump and the first electrical terminal at the first die surface.

15. The semiconductor device of claim 2, wherein the semiconductor die includes a stacked die.

16. The semiconductor device of claim 2, wherein the semiconductor die includes a plurality of first electrical terminals at the first die surface and a plurality of corresponding first conductive bumps coupled to each of the plurality of electrical terminals; and
wherein the recessed terminal area covers at least two of the plurality of first conductive bumps, and wherein the second electrical terminal is coupled to the at least two of the plurality of first conductive bumps in the recessed terminal area.

17. The semiconductor device of claim 16, wherein the dielectric includes a polymer configured to be activated to conductive plating deposition using laser ablation, and wherein the recessed terminal area includes a recess created using laser ablation of the second dielectric surface; and
wherein the second electrical terminal includes a laser activated conductive plating deposition in the recessed terminal area.

18. A semiconductor device comprising:
a semiconductor die having a first die surface and a plurality of first electrical terminals at the first die surface;
a plurality of first conductive bumps corresponding to each of the plurality of electrical terminals at the first die surface, each of the first conductive bumps having a first bump surface coupled to one of the plurality of electrical terminals and having a second opposite bump surface;
a dielectric substantially covering the first die surface and substantially surrounding the plurality of first conductive bumps between the first and second bump surfaces of each first conductive bump, the dielectric having a first dielectric surface proximate the first die surface and a second dielectric surface opposite the first dielectric surface, the second dielectric surface including a recessed terminal area;
a second electrical terminal coupled to at least one of the second bump surfaces in one of the recessed terminal configured to provide an electrical connection to at least one of the plurality of first electrical terminals at the first die surface;
wherein the dielectric includes a polymer configured to be activated to plating deposition using laser ablation, and wherein the recessed terminal area includes a recess created using laser ablation of the second surface; and
wherein the second electrical terminal includes a laser activated conductive plating deposition in the recessed terminal area.

19. The semiconductor device of claim 18, wherein the plurality of first conductive bumps include a plurality of first Cu bumps, wherein the polymer includes a polymer configured to be activated to copper plating deposition using laser ablation, and wherein the second electrical terminal includes a laser activated copper plating deposition.

20. The semiconductor device of claim 18, wherein the recessed terminal area includes at least one second bump surface of one or more of the plurality of first conductive bumps.
